(19) United States
(12) Patent Application Publication
(10) Pub. No.: US 2023/0333176 A1
(43) Pub. Date: Oct. 19, 2023

(54) Method for Identifying a Leakage Current Path in a Circuit

(71) Applicant: Dialog Semiconductor (UK) Limited, London (GB)

(72) Inventors: Indrajit Manna, Cheltenham (GB); Russell Giles, Southrop (GB); Peter Bell, Wokingham (GB)

(21) Appl. No.: 17/719,828

(22) Filed: Apr. 13, 2022

(51) Int. Cl. G01R 31/52

(52) U.S. Cl. CPC G01R 31/52

(57) ABSTRACT

A method for detecting a leakage current path in a circuit is presented. The method may be used for identifying a leakage current path in an analog circuit and induced by the presence of a high voltage. The method includes several steps. A circuit design description of the circuit is received. The circuit design description is then interrogated to identify a set of candidate components having a first terminal coupled to a voltage source adapted to provide a voltage above a predefined value. Then for each electronic component in the set, a second terminal coupled to ground is searched. Upon identification of the second terminal coupled to ground a leakage path is reported. The method may be used for identifying a leakage current path induced by the presence of a high voltage in conjunction with the presence of parasitic devices.

### RELATED PATENT APPLICATIONS

This application is related to U.S. patent application Ser. No. 17/019,851, filed on Sep. 14, 2020, assigned to the same assignee as the present invention, and incorporated herein by reference in its entirety, and to U.S. patent application Ser. No. 17/072,293, filed on Oct. 16, 2020, assigned to the same assignee as the present invention, and incorporated herein by reference in its entirety.

### TECHNICAL FIELD

The present disclosure relates to a method for identifying a leakage current path in an electronic circuit. In particular, the present disclosure relates to a method for identifying a leakage current path in an analog circuit and induced by the presence of a voltage, such as a high voltage.

### BACKGROUND

In analog electronic circuits a node may become floating under some stimulus conditions. This may be caused by absence of low-resistance DC discharge paths from the node to a rail voltage Vdd or to ground Vss. When this results in a floating node accumulating electrical charge, it can float the gates of some devices connected to it and create a conducting path(s) between Vdd and Vss.

In a small number of cases, particularly in power management integrated circuits (ICs) using high-voltage (HV) devices, leakage may be caused by high-voltage nodes turning on parasitic devices (such as an NPN bipolar junction transistor) in parallel with a MOSFET. If a conducting path already existed between the channel terminals of devices to Vss, then a complete leakage path may be created between high-voltage terminals and the Vss node. Such a leakage is difficult to detect in simulation for several reasons. Firstly, the parasitic bipolar device is often not modelled and therefore, by doing simulation only, one cannot detect the leakage path. Secondly, if parasitic bipolar models are available, they introduce extra nodes, devices and complexities in circuit simulation. This makes the simulation slower and the results less intuitive. Thirdly, the designer may only want to identify the specific topologies that cause the leakage and is not interested in the actual value of the leakage.

Commercial tools for floating node detection involve some form of transient simulation and cannot generally easily identify high voltage induced floating nodes without parasitic bipolar modelling.

As on-chip high-voltage is scaled up due to demand from specific applications, various leakage mechanisms are expected to appear in circuits. Such leakage mechanisms may not only originate from P-body/Deep N-well junctions, but also from gate-induced drain leakage, subthreshold leakage in a MOS device, N-well to N-well leakage, just to name a few. While it is possible to create device models for leakage, it takes time and requires foundry support as well as additional circuit complexity and simulation time.

### SUMMARY

There is therefore a need for a method allowing the identification of high-voltage-induced leakage paths without reliance on models or simulation.

It is an object of the disclosure to address one or more of the above mentioned limitations.

According to a first aspect of the disclosure, there is provided a method for detecting a leakage current path in a circuit, the method comprising receiving a circuit design description of the circuit; interrogating the circuit design description to identify a set of candidate components having a first terminal coupled to a voltage source adapted to provide a voltage above a predefined value; for each electronic component in the set searching for a second terminal coupled to ground; and upon identification of the second terminal coupled to ground reporting a leakage path.

For instance, the predefined value may be defined by the user based on the normal operating voltage of the electronic circuit and the breakdown of any part of the electronic component, such as a junction.

Optionally, the method further comprises for each electronic component in the set, interrogating the circuit design description to identify a third terminal adapted to control a state of the electronic component.

For instance, the third terminal may be a control or enabling terminal such as a gate terminal.

Optionally, the method further comprises searching for a conductive path between the third terminal and ground or between the third terminal and a circuit port configured to receive a supply voltage, and upon identification reporting a leakage path.

Optionally, wherein the list of candidate components comprises one or more switch devices having an isolation terminal and a drain terminal, and wherein the first terminal is an isolation terminal, and the second terminal is a drain terminal.

Optionally, wherein the said one or more switch devices comprise a butted source terminal.

Optionally, the method further comprises interrogating the circuit design description to identify a conductive path between the butted source terminal and ground or between the butted source terminal and a circuit port configured to receive a supply voltage; and upon identification reporting a leakage path.

Optionally, wherein the said one or more switch devices are N-type devices. For instance the N-type devices may be NMOS switches.

Optionally, the method comprises identifying from circuit design description electronic components comprising both the first terminal and the second terminal.

Optionally, wherein a conductive path is identified between two nodes via at least one of: a direct connection, a resistive connection, a connection including one or more switches in a closed state, a connection including one or more forward-biased diodes, a connection including one or more a diode connected transistors; or a combination of such connections.

Optionally, the predefined value is defined based on a breakdown voltage of a certain part an electronic component of the circuit. For instance the breakdown voltage may be the breakdown voltage of a junction within the electronic component. For example, the predefined value may be dictated by the circuit design and application. It may be close to but less than the breakdown voltage.

Optionally, the circuit design description comprises a list of electronic components present in the circuit and connectivity information. For instance, the circuit design description may comprise a netlist including component data, connectivity data, circuit port data etc. The circuit design description may also include a technology library containing structural information about individual device types.

Optionally, wherein the circuit design description comprises a circuit data structure providing a node connectivity representation.

Optionally, wherein interrogating the circuit design description comprises traversing the circuit data structure. For instance, traversing the circuit data structure may include crawling the node connectivity representation. For example, a voltage port may be propagated iteratively inside the data structure.

According to a second aspect of the disclosure there is provided a detection system for detecting leakage current paths in a circuit, the detection system comprising a processor configured to perform the steps of the method according to the first aspect.

According to third aspect of the disclosure there is provided a non-transitory computer-readable data carrier having stored thereon instructions which when executed by a computer cause the computer to carry out the method according to the first aspect.

### BRIEF DESCRIPTION OF THE DRAWINGS

The disclosure is described in further detail below by way of example and with reference to the accompanying drawings, in which:

FIG. 1 is a is a cross-section of a high-voltage NMOS field-effect transistor with a parasitic bipolar junction;

FIG. 2 is a is a flow chart of a method for identifying a voltage-induced leakage current path, according to the disclosure;

FIG. 3 is a flow chart illustrating an exemplary implementation of the method of FIG. 2;

FIG. 4A-4D are diagrams illustrating a path search sequence according to the method of FIG. 3;

FIG. 5A is a diagram of a high-voltage device having two N-wells;

FIG. 5B is a diagram of high-voltage device having a N+ region connected to a high voltage terminal and a gate connected to a sink terminal;

FIG. 5C is diagram of a high-voltage device having a high voltage terminal, a sink terminal and an enabling terminal;

FIG. 6 is a flow chart illustrating another exemplary implementation of the method of FIG. 2;

FIG. 7 is a schematic diagram of a detection system for detecting leakage current paths in a circuit;

FIG. 8 is an example of a data structure comprising a circuit graph.

### DETAILED DESCRIPTION

FIG. 1 is a cross-section of a high-voltage N type metal-oxide-semiconductor field-effect transistor. The NMOSFET transistor 100 is made of four portions that include a P-body 110, a deep N-well 120 and two heavily doped regions referred to as N+ portions 130a and 130b. The transistor 100 has four terminals: a gate terminal, a drain terminal connected to the N+ portion 130b, an isolation terminal connected to the deep N-well 120 and a so called butted source terminal connected to both the P-body 110 and the N+ portion 130a. An inner parasitic bipolar transistor 140 is formed by the deep N-well 120, the P-body 110 and the drain terminal. In some applications the isolation terminal can be coupled to a high voltage which reverse bias the Deep N-well/P-body junction. If the reverse-biased junction between N-well and P-body gets close to breakdown and if conducting paths to supplies are available from the butted source and from the drain, then the parasitic bipolar device 140 may turn on. As a result a leakage current may flow between the isolation terminal and the drain terminal (short-circuit leakage path), hence increasing standby leakage and power drainage from the battery/supply even when main field-effect transistor formed by the source/gate/drain is turned off.

It is noted that for most high-voltage devices, a butted source structure is the default configuration. As explained above, for the parasitic bipolar transistor to turn on, the base current must be provided. Since the base of parasitic bipolar of a high-voltage NMOS device is P-well it needs to be connected to the source to provide a conducting path to a supply.

As technology is scaled down, the junction breakdown voltage is expected to gradually decrease in each generation. The parasitic bipolar devices are also becoming stronger due to changing doping profiles of the emitter, base and collector regions in advanced technologies. These trends, added with the requirement of generating on-chip high-voltage source in applications such as display drivers, chargers and DC-DC converters will make it essential to detect high-voltage induced floating node leakage in future designs.

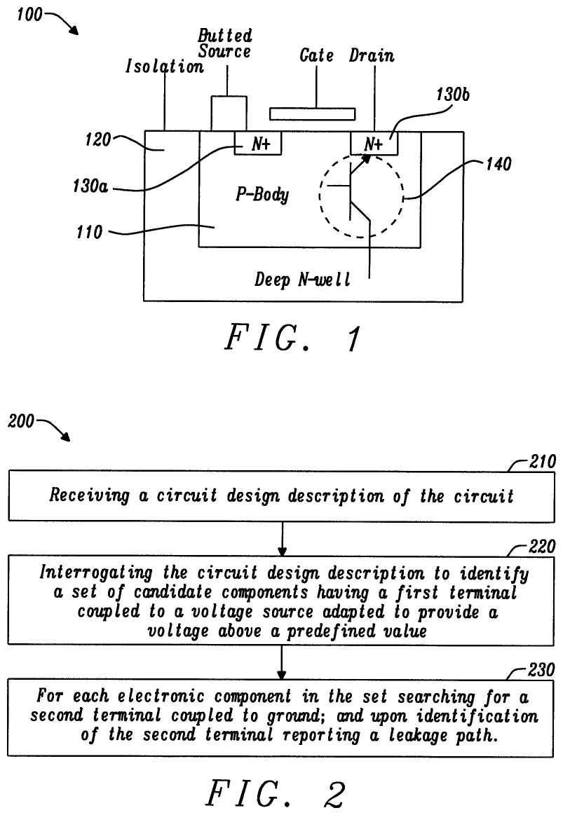

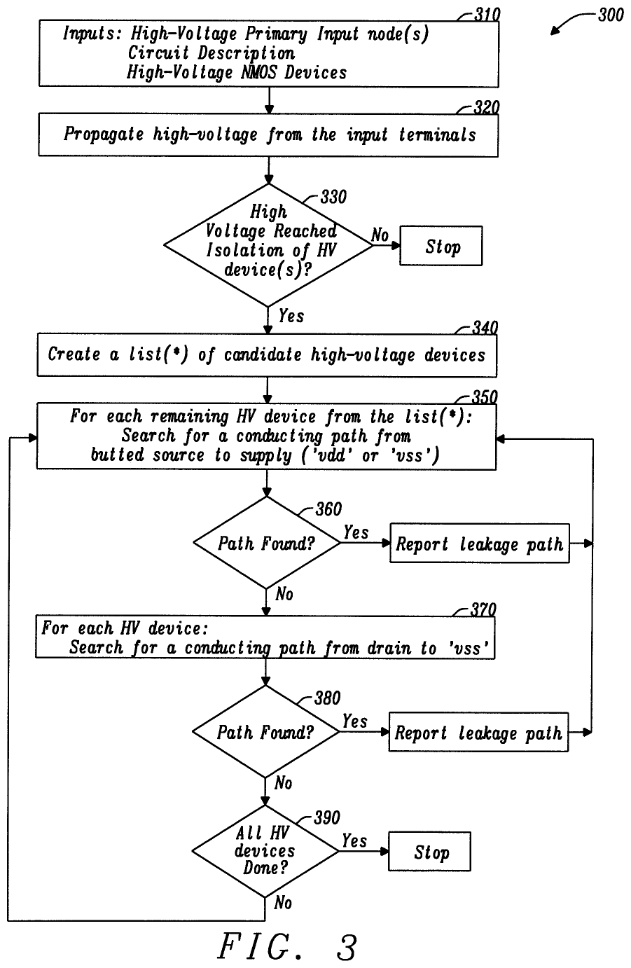

FIG. 2 is a flow chart of a method for identifying a voltage-induced leakage current path in a circuit. For instance, the method may be used for identifying a leakage current path induced by the presence of a high voltage in conjunction with the presence of parasitic devices.

At step 210 a circuit design description of the circuit is received. For instance the circuit design description may include a list of electronic components present in the circuit and connectivity information such as component data, connectivity data, circuit port data, among others. Circuit design description may include a netlist that is a known structured text or other circuit description listing all the components of the circuit and the nodes that they are connected to. The circuit design description may also include a technology library containing structural information about individual device types.

At step 220 the circuit design description is interrogated to identify a set of candidate components. The candidate components have a first terminal coupled to a voltage source adapted to provide a voltage above a predefined value.

The first terminal may be referred to as the high voltage terminal. The predefined value may be defined based on a breakdown voltage of a certain part an electronic component of the circuit. The breakdown voltage may be the breakdown voltage of a junction within the electronic component such as a high-voltage junction. The so-called high-voltage junctions are junctions with high breakdown voltage and normal operating voltage (i.e lower than the breakdown voltage of the high-voltage junctions) in a given circuit. A high voltage in this context is a voltage that is substantially higher than the voltage necessary for normal operation of standard logic and analog circuits but lower than (but close to) the breakdown voltage of high-voltage junctions.

The predefined value may be chosen to be close but less than the breakdown voltage. The breakdown voltage may be a voltage above which the device/component is expected to fail or be damaged.

At step 230, for each electronic component in the set a second terminal coupled to ground is searched. A leakage path is reported upon identification of the second terminal coupled to ground.

The circuit design description of the circuit received at step 210 may include a netlist in which circuit components may be represented as cells or blocks having one or more terminals. The components may be for example logic cells from a standard cell library, transistors, resistors, capacitors, functional circuit blocks, and so on. For each type of components, multiple instances will generally be present in a circuit.

A list of supply connected nodes may also be provided either as part of a netlist or separately. The supply connected nodes may include a high power supply port for instance a high voltage port Vdd (HV), a lower power supply port, for instance a lower voltage port Vdd (non HV) and a ground port Vss.

One can visualize any circuit as a directed graph where each node of the graph is a circuit node and each device (such as a transistor, diode or resistor) provides a possible path in or out of the node. Instead of simulating the high-voltage devices (for instance NMOS transistors) with accurate models of the parasitic bipolar transistors, one can simply trace through the circuit graph and check for the above conditions and report a possible leakage path.

For instance, the circuit design description may include a circuit data structure providing a node connectivity representation. The data structure may comprise a node connectivity representation which may have any of an adjacency matrix, adjacency list, and an edge list and may be constructed in various ways. For example, the data structure may comprise an associative array in which the keys are the nodes' names and the value of each key is a connectivity list of device component terminals connected to it. The data structure does not have to be a graphical representation. A simpler structure such as a stack-based structure can also be used for traversal through a circuit connectivity.

The netlist may be transformed to create a data structure with the appropriate properties. Examples of data structures are provided in patent applications U.S. Ser. No. 17/019,851 and U.S. Ser. No. 17/072,293. In some embodiments, the data structure comprises a circuit graph and interrogating the data structure comprises crawling the circuit graph via one or more crawling episodes.

In an electronic circuit, one might expect high voltage induced leakage issue in several circumstances. In this example a circuit with several NMOSFET transistors is considered. Leakage may become a concern if each of the following conditions becomes true.
i) The high-voltage provided is closer to junction breakdown of the high-voltage N-well. As mentioned above a high voltage refers to a voltage which is significantly higher than the normal operating voltage of a circuit but below the breakdown voltage.
ii) The source of the NMOSFET is butted with the body. If this terminal is connected to Vss or to a supply which is not a high-voltage supply (directly or through a conducting path) it can provide a leakage path from the high-voltage device.
iii) Alternatively, if the source of the NMOSFET is floating and the drain has a conducting path to Vss directly or through a conducting path, the NPN parasitic bipolar transistor (formed by high-voltage N-well, P-body and the drain of the high-voltage NMOS) can turn on if the high-voltage is applied across the reverse-biased isolation/P-body junction.

FIG. 3 is a flow chart illustrating an exemplary implementation of the method of FIG. 2.

The method or algorithm 300 to detect voltage-induced leakage path is described as follows:

At step 310 a circuit design description of the circuit is received that may include for instance a netlist.

At step 320 the high voltage input nodes of the circuit are identified and the netlist is interrogated by tracing through the netlist from each primary input or circuit port that has a high voltage Vdd (HV) applied to it. A high voltage may be defined by a voltage level that is: i) substantially higher than the voltage necessary to drive standard logic and analog circuits, and ii) close to the breakdown voltage of the Deep N-well of the high voltage NMOS devices of interest. Normal operating voltage of standard cell libraries and analog circuit may range between about 1.5V-3.0V. High-voltage junction breakdown may be in the range of about 12V-24V. It will be appreciated that these values may change depending on the technology being used.

At step 330, if a high voltage is connected to the isolation terminal of any high-voltage NMOS device, then the instance name of the device is recorded to create a list of candidate high-voltage devices (step 340), otherwise the method is stopped.

At step 350, for each high-voltage NMOS device among the candidate high-voltage devices, it is determined if the device has a butted source. Then for the butted source devices the circuit netlist is interrogated to determine if the butted source is connected to a supply (either a Vss node or a Vdd node at a voltage lower than the high voltage) either directly or through a conducting path. The precise value of the voltage is not important if the voltage is lower than the high voltage we are considering.

At step 360, if a path is found, the leakage path from the HV device to the supply is reported.

At step 370, if the butted source is a floating node (i.e. it has no conducting path to supply Vdd or ground Vss), then the netlist is interrogated to search for the drain terminal of the same HV device and trace through the circuit netlist to find if a conducting path is found between the drain terminal to Vss node.

A conducting path may be formed by any of the following components (or a series combination thereof): a) A direct short, b) A resistive short, c) A regular MOSFET with gate turned on, d) Forward-biased diode, e) a Diode connected MOSFETs (single or stacked devices).

At step 380 if a conducting path is found, this path is reported as a potential leakage path.

The process is then repeated for all high voltage devices identified in the list of candidate devices. When all high-voltage devices are exhausted at step 390, the method stops.

It will be appreciated that depending on the gain of the NPN transistor and how close the breakdown voltage of the N-well/P-well junction is relative to the high voltage being applied, the leakage may not be significant. For example, if the junction breakdown voltage is 24V and the high voltage applied is only 16V, it is highly unlikely that NPN will turn on.

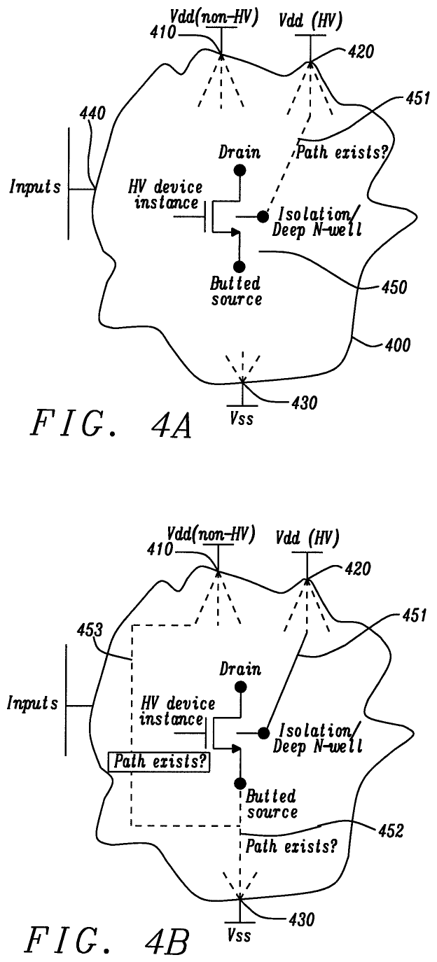

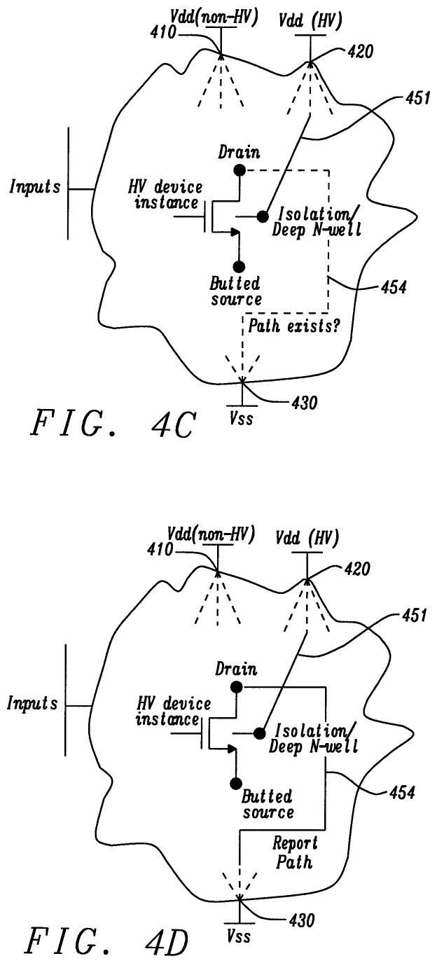

FIGS. 4A-4D illustrate a sequence of paths searched for high-voltage induced leakage. As explained above the search may be based on a graph search. The paths being searched are shown in broken lines and when a conducting path is found, the corresponding connection is shown as a plain line. An electronic circuit 400 is shown with several ports, a first port 410 for receiving a voltage below a certain value and referred to as Vdd (non-HV), a second port 420 for receiving a second voltage above a certain value, referred to as high voltage Vdd (HV), a ground port Vss 430 and another port 440 for receiving various inputs. The inputs at port 440 are assumed to be non high-voltage inputs. The port 420 also referred to high voltage port, may for instance receive a supply voltage from power supply such as a switching power converter (including a buck-boost or a boost converter), or a charge pump.

The circuit 400 includes a high voltage device 450 provided with a gate terminal, a drain terminal, a butted source terminal and an isolation terminal.

In this example the high voltage device 450 is a high-voltage NMOS device with butted source.

In FIG. 4A, the presence of a conduction path 451 between the isolation terminal of 450 and the high voltage port 420 is searched (step 330). A conductive path does not necessarily imply a direct connection and may be achieved through several conducting devices.

When the isolation terminal of a high-voltage NMOS device with butted source is detected to be electrically connected to the high-voltage terminal 420 of the circuit, the device instance name is added to the list of candidate high-voltage devices (step 340).

In FIG. 4B an electrical connection 451 between the isolation terminal of 450 and the high-voltage terminal 420 of the circuit has been found and is shown as a plain line.

The netlist is now interrogated to look for a conductive path between the butted source terminal of the candidate high-voltage device 450 to either the first port 410 Vdd (non-HV) or the ground port 430 Vss. In this example, a potential path 452 is shown in broken lines between the butted source terminal and ground, and a potential path 453 is shown in broken lines between the butted source terminal and the first port 410. Both paths 452 and 453 are unlikely to exist simultaneously for given node as this would indicate a direct short from Vdd to Vss. A leakage will be generally higher if a path 452 to Vss is found (compared a path 453 to Vdd).

If a conductive path exists between the butted source terminal of 450 and the first port 410 Vdd (non-HV) or the ground port 430 Vss, then the algorithm reports the leakage path (step 360).

If the butted source terminal is floating (that is no conductive path has been found between the butted source terminal and port 410 or port 430, then the method goes to step 370 and searches for a potential path 454 between the drain terminal of 450 and the ground port 430 as illustrated in FIG. 4C. If the path 454 does not exist, the device is discarded and the next candidate high-voltage device from the list is selected.

FIG. 4D illustrates the case when an electrically conducting path is found between the drain of the high-voltage device and Vss. The path 454 is shown as a plain line. The presence of paths 451 and 454 means that the required conditions are met for a parasitic bipolar transistor to exist and the leakage path from the high-voltage port 420 to ground Vss 430 is reported (step 380).

The method described above with reference to FIGS. 3 and 4A-4D is presented using reverse-biased N-well/P-body junction in a high-voltage butted-source NMOS as the primary leakage inducing mechanism. However, the method can be used with any leakage producing device such as a gate-overlapped drain region, subthreshold leakage, N-well to N-well leakage to name a few.

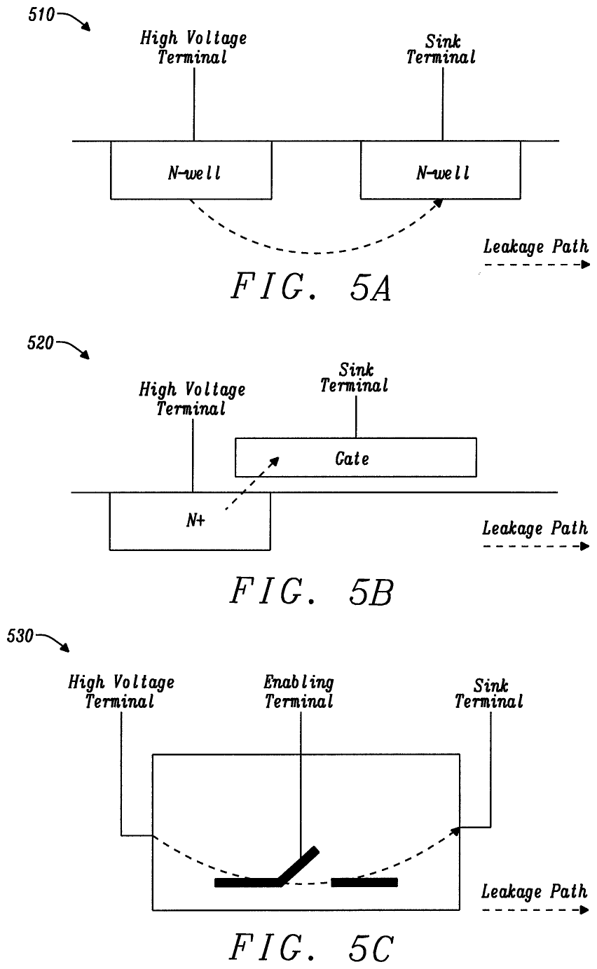

FIGS. 5A-5C illustrate several exemplary devices that may cause a voltage-induced leakage in a circuit.

FIG. 5A shows a device 510 having two N-wells. The first N-well is connected to a first terminal for which a high voltage can be applied, referred to as the high-voltage (HV) terminal. The second N-well is connected to a second terminal for which a leakage path can be created from the high-voltage terminal and referred to as a sink terminal. A leakage path shown in dotted lines may be present between the two N-wells when the high voltage terminal receives a high voltage and when the sink terminal is coupled to ground.

FIG. 5B shows a device 520. The device 520 has a N+ region connected to a high voltage terminal and a gate connected to a sink terminal. A leakage path may occur between the high voltage terminal and the gate when the high voltage terminal receives a high voltage and when the sink terminal is coupled to ground. Only a planar configuration is shown but vertical configuration is also possible.

FIG. 5C shows an arbitrary device having a high voltage terminal, a sink terminal and an enabling terminal, also referred to as control terminal. The arbitrary device 530 can produce a leakage path only when a high voltage is applied at the high-voltage terminal and the enabling terminal is asserted and when the sink terminal is coupled to ground.

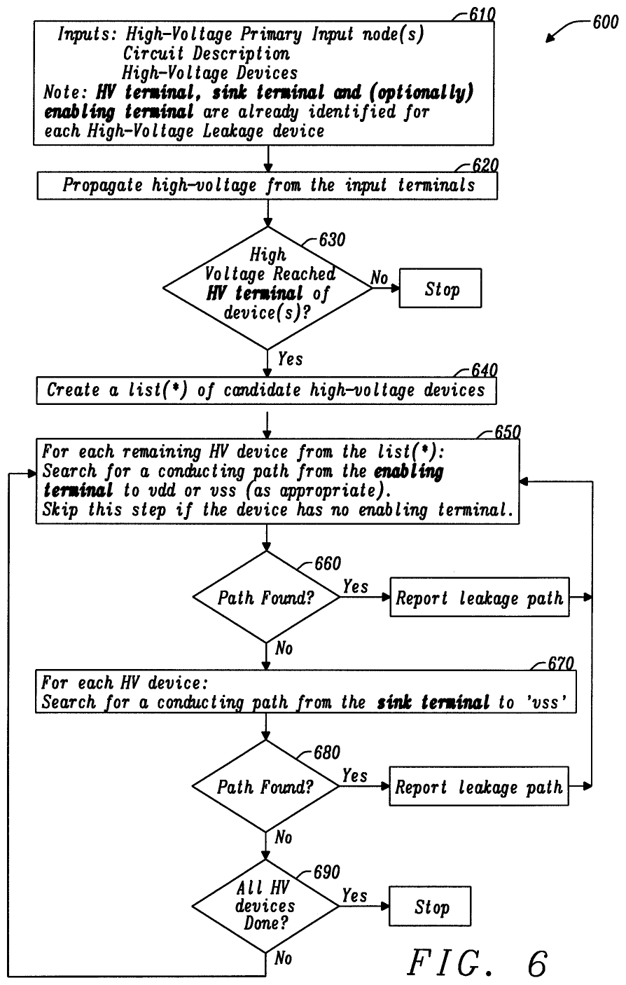

FIG. 6 is a flow chart illustrating another exemplary implementation of the method of FIG. 2. The method 600 may be applied to an arbitrary high-voltage device.

At step 610 a circuit design description of the circuit is received. The circuit design description may take different forms, for instance it may include a technology library containing structural information about individual device types and a netlist containing connectivity information for the devices.

The circuit design description is interrogated to identify device terminals for which a high voltage can be applied, referred to as the high-voltage (HV) terminal. Typically, this will be a N+ or N-well terminal of a device. Due to the oxide breakdown voltage, a high voltage terminal is unlikely to be a gate terminal. Then device terminals are identified for which a leakage path can be created from the identified high-voltage terminal. Such a terminal is referred to as a sink terminal. Identification of high-voltage devices and their terminal designation (such as a high-voltage, enabling and sink terminals) may be obtained or computed from the technology library. This step may be performed before the circuit is analyzed.

Optionally, the device may have one or more control or enabling terminals that need to be set to a certain state (for example switched on or switched off) in order for the leakage path to be activated. A high-voltage device may or may not have any enabling terminal. If no enabling terminal is present, the leakage path is considered unconditional upon application of a high voltage at the HV terminal.

Once the high voltage terminals, sinks terminals and optionally enabling terminals have been identified for a list of devices, the method passes to steps 620 and 630.

At step 620, the netlist is interrogated by tracing through the netlist from each primary input or circuit port that has a high voltage Vdd (HV) applied to it and find if a high voltage reached the HV terminal of a device (630).

At step 640, if a high voltage is connected to the HV terminal of a device (630), the instance name of the device is recorded in a list of candidate high-voltage devices that may lead to a leakage path.

At step 650, a device from the list of candidate devices is selected if it has an enabling terminal, otherwise step 650 is skipped. Then the circuit netlist is interrogated to determine if the enabling terminal of the device is connected to an appropriate supply (Vdd) or ground (Vss) to activate the HV device. If a connection is found at step 660, the leakage path is reported, otherwise if the enabling terminal is floating the method moves to step 670.

At step 670 the netlist is interrogated to find if a conducting path exists between the sink terminal of the device and ground (Vss). A conducting path may be formed by any of the following components (or a series combination thereof): a) A direct short, b) A resistive short, c) A regular MOSFET with gate turned on, d) Forward-biased diode, e) Diode connected MOSFETs (single or stacked devices).

At step 680 if a conducting path is found, this path is reported as a potential leakage path.

The process is then repeated iteratively for all high voltage devices listed as candidate device. When all high-voltage devices are exhausted, the method stops.

The methods of the disclosure as described with references to FIGS. 1 to 6 permit to quickly identify circuit topologies that are at a risk of developing voltage induced floating nodes and leakage paths. The methods are based on structural analysis of the circuit netlist and do not rely on device models, which significantly reduces the engineering overheads, cost, and simulation effort.

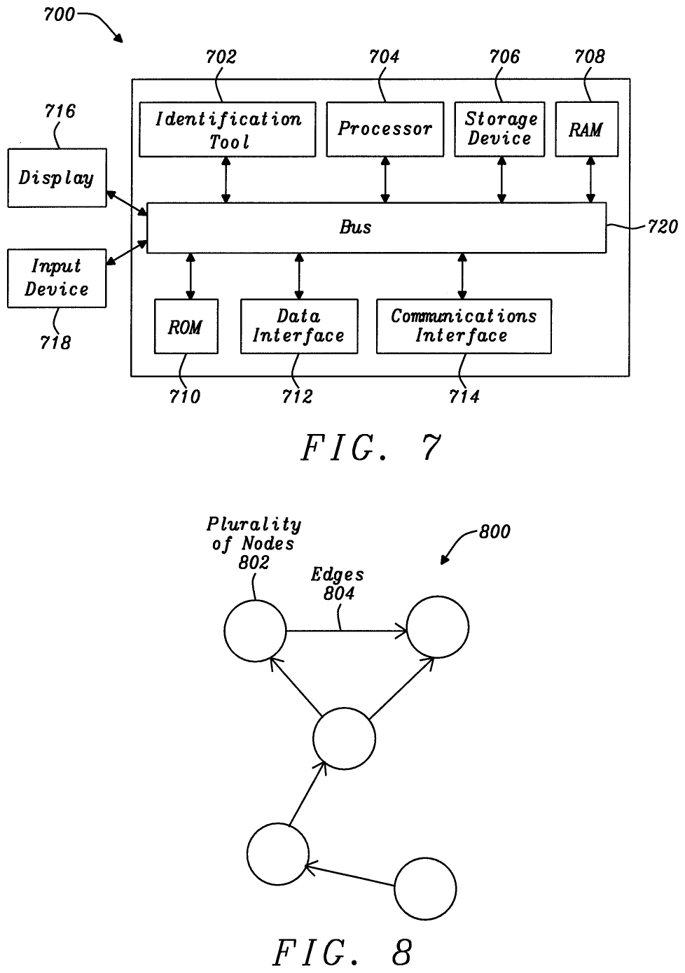

FIG. 7 is a schematic diagram of a detection system 700 for detecting leakage current paths in a circuit. The detection system 700 comprises modified components for carrying out the methods of the disclosure.

The system 700 includes a software engine, data carrier or algorithm 702 configured as an identification tool for implementing the methods of the disclosure. A processor 704 is provided to load and execute the identification tool 702.

The system 700 also comprise other components including a storage device 706, RAM 708, ROM 710, a data interface 712, a communications interface 714, a display 716, an input device 718, and a bus 720 to enable communication between the different components.

A user may interact with the system 700 using the display 716 and the input device 718 to instruct the system 700 to implement the methods of the disclosure in the testing of a circuit.

FIG. 8 is an example of a data structure comprising a circuit graph. The data structure 800 comprises a plurality of nodes 802 connected via edges 804. The nodes may be alternatively referred to as vertices or points, and the edges may be alternatively referred to as links or lines. Each node 802 represents a circuit node such as a terminal of a circuit component, and each edge 804 represents a circuit component. One circuit component may be represented by a plurality of edges wherein each of the edges represents a different electrical path through the component. In some embodiments, the edges 804 are directed edges, as shown by the arrows in FIG. 8, with the directionality representing a direction of current flow or decreasing voltage. The direction of a specific edge 804 can change as the input conditions of the circuit change, e.g. due to the digital inputs being toggled.

The data structure 800 can be configured. For example, edges between nodes can be modified, added or removed based on the value at another node. The data structure may be created so that it can be traversed across all connected nodes. A traversal is a journey that starts at a certain node, follows the edges outgoing from that node, reaches another node (and so on) and finally reaches a destination node. The direction of the traversal follows a direction of control, which is a path following a sequence of events reflecting the control or effect that one node has on a subsequent node. When all traversals are completed, voltage states of all nodes are determined for the circuit.

Traversing the data structure may be achieved by a data processing system provided with instructions which can trace a path through successive nodes in the structure.

A skilled person will therefore appreciate that variations of the disclosed arrangements are possible without departing from the disclosure. Accordingly, the above description of the specific embodiments is made by way of example only and not for the purposes of limitation. It will be clear to the skilled person that minor modifications may be made without significant changes to the operation described.

1. A method for detecting a leakage current path in a circuit using a detection system comprising a data interface, a processor, and a software engine, the method comprising:
receiving at the data interface, a circuit design description of the circuit;
interrogating the circuit design description by executing the software engine to identify a set of candidate components having a first terminal coupled to a voltage source adapted to provide a voltage above a predefined value;
for each electronic component in the set searching for a second terminal coupled to ground; and upon identification of the second terminal coupled to ground reporting a leakage path.

2. The method as claimed in claim 1, further comprising for each electronic component in the set, interrogating the circuit design description to identify a third terminal adapted to control a state of the electronic component.

3. The method a claimed in claim 2, further comprising searching for a conductive path between the third terminal and ground or between the third terminal and a circuit port configured to receive a supply voltage, and upon identification reporting a leakage path.

4. The method as claimed in claim 1, wherein the set of candidate components comprises one or more switch devices having an isolation terminal and a drain terminal, and wherein the first terminal is an isolation terminal, and the second terminal is a drain terminal.

5. The method as claimed in claim 4, wherein the said one or more switch devices comprise a butted source terminal.

6. The method as claimed in claim 5, further comprising interrogating the circuit design description to identify a conductive path between the butted source terminal and ground or between the butted source terminal and a circuit port configured to receive a supply voltage, and upon identification reporting a leakage path.

7. The method as claimed in claim 4, wherein the said one or more switch devices are N-type devices.

8. The method as claimed in claim 1, comprising identifying from circuit design description electronic components comprising both
the first terminal and the second terminal.

9. The method as claimed in claim 1, wherein a conductive path is identified between two nodes via at least one of: a direct connection, a resistive connection, a connection including one or more switches in a closed state, a connection including one or more forward-biased diodes, a connection including one or more a diode connected transistors, or a combination of such connections.

10. The method as claimed in claim 1, wherein the predefined value is defined based on a breakdown voltage of a certain part of an electronic component of the circuit.

11. The method as claimed in claim 1, wherein the circuit design description comprises a list of electronic components present in the circuit and connectivity information.

12. The method as claimed in claim 11, wherein the circuit design description comprises a circuit data structure providing a node connectivity representation.

13. The method as claimed in claim 12, wherein interrogating the circuit design description comprises traversing the circuit data structure.

14. A detection system for detecting leakage current paths in a circuit, the detection system comprising a processor configured to perform the steps of the method of claim 1, a data interface, and a software engine.

15. A non-transitory computer-readable data carrier having stored thereon instructions which when executed by a computer cause the computer to carry out the method of claim 1.
